(19) United States
(12) Patent Application Publication
(10) Pub. No.: US 2025/0314603 A1
(43) Pub. Date: Oct. 9, 2025

(54) METHOD OF OBTAINING A MODIFIED IMAGE OF A SPECIMEN

(71) Applicant: Oxford Instruments Nanotechnology Tools Limited, Oxon (GB)

(72) Inventors: Robert Masters, Bucks (GB); Angus Bewick, Bucks (GB); Philippe Pinard, Bucks (GB); Peter Statham, Bucks (GB)

(73) Assignee: Oxford Instruments Nanotechnology Tools Limited, Oxon (GB)

(21) Appl. No.: 19/171,988

(22) Filed: Apr. 7, 2025

(30) Foreign Application Priority Data
Apr. 8, 2024 (GB) 2405000.7

(51) Int. Cl. G01N 23/2251; G06T 5/77

(52) U.S. Cl. CPC G01N 23/2251; G06T 5/77; G01N 2223/303; G01N 2223/401; G01N 2223/501; G01N 2223/505; G06T 2207/10061

(57) ABSTRACT

A method of obtaining an image of a specimen in a scanning electron microscope, the image being modified by way of compensating for detector afterglow effects, is provided. The method includes: acquiring first image data, the first image data including a plurality of pixels having values representing monitored electrons emitted from the specimen, at a plurality of locations within a region thereof as a result of an electron beam of the scanning electron microscope impinging upon the plurality of locations, and incident upon a scintillator member of an electron backscatter diffraction, EBSD, detector, and generating a modified image including a plurality of pixels each having a value calculated based on the value of a corresponding pixel of the first image data and an afterglow model representative of a luminescence persistence characteristic of the scintillator member. A system and computer program product are also provided.

### FIELD

The present invention relates to a method of obtaining a modified image of a specimen in a scanning electron microscope (SEM) using an electron backscatter diffraction (EBSD) detector, an in particular to obtaining an image modified by way of compensating for detector afterglow effects.

### BACKGROUND

Most commercial EBSD detectors employ a scintillator member, typically in the form of a phosphor screen, which converts incident electrons to a light pulse for imaging. All phosphor screens have a luminescence persistence characteristic; that is, the screen glows for a period after being struck by an electron. This afterglow period, which may be quantified as a persistence lifetime, is typically in the order of milliseconds. As a result, the detector has a finite response time. That is, changes to the electron signal incident on the phosphor screen are not instantaneous and are only fully reflected by data output by the detector after a few milliseconds. Practically, this luminescence persistence, which is also called phosphor persistence, means that each new electron signal output by the detector contains a ‘ghost’ of previously acquired signals. These afterglow effects appear as various deleterious image artefacts depending in EBSD images, depending on the way in which the image data is acquired.

In addition to the phosphor detector screen, EBSD detectors typically also include diodes arranged around the screen so as to capture electrons scattered in a forward direction due to the sample tilt. These detectors are referred to as forward-scatter detectors or forescatter diodes (FSDs). FSDs have conventionally been used to collect high-intensity, high-contrast images of tilted surfaces on scanning electron microscope (SEM) specimens. Thus FSDs have been used to provide complementary image data prior to acquiring quantitative EBSD data, and to facilitating the surveying of specimens to identify regions of interest for EBSD analysis.

Recent developments in detector technology, in particular to the acquisition speeds that may be achieved, have enabled EBSD detector screens themselves to be used to generate complementary microstructural images in a manner analogous to techniques that use FSDs. These recent approaches involve defining one or more regions of the EBSD detector screen as ‘virtual’ forescatter diodes (virtual FSDs, or VFSDs). This technique is described in Wright et al. “Electron imaging with an EBSD detector”, Ultramicroscopy Vol. 148, 2015, pp. 132-145, ISSN 0304-3991, https://doi.org/10.1016/j.ultramic.2014.10.002. A VFSD may be used to capture an electron image by scanning the electron beam across the specimen in a series of points and integrating the total signal captured within the VFSD region of the detector screen. In practice, these electron images are comparable to those captured with physical FSDs mounted above and below the detector screen of some EBSD detectors.

Conventionally, luminescence has not been considered problematic for VFSD imaging, where adequately fast-decaying phosphor screens have been used. However, when acquiring VFSD images at higher speeds, scintillator afterglow effects become more apparent, and are typically manifested as horizontal streaking and poor spatial resolution.

There is a need for an SEM imaging technique that can provide the beneficial flexibility afforded by using the EBSD detector as an imaging device, while mitigating the streaking and blurring artefacts that are suffered as a consequence of detector screen afterglow and are expected to become increasingly problematic as acquisition speeds increase.

### SUMMARY

In accordance with a first aspect of the invention there is provided a method of obtaining a modified image of a specimen in a scanning electron microscope, the method comprising: acquiring first image data, the first image data comprising a plurality of pixels having values representing monitored electrons emitted from the specimen, at a plurality of locations within a region thereof as a result of an electron beam of the scanning electron microscope impinging upon the plurality of locations, and incident upon a scintillator member of an electron backscatter diffraction, EBSD, detector, and generating a modified image comprising a plurality of pixels each having a value calculated based on the value of a corresponding pixel of the first image data and an afterglow model representative of a luminescence persistence characteristic of the scintillator member.

The inventors have realised that afterglow correction techniques may advantageously be applied to electron imaging data acquired using an EBSD detector in an SEM, in order to produce images with the flexibility of analysis type and experimental application and the reduced costs and complexity that are afforded by EBSD-based imaging, while doing so at high speeds, and, importantly, while addressing the issue of the persistence artefacts that are associated with this detector technology. Moreover, the method mitigates detector screen afterglow without the need to use faster scintillator materials having shorter persistence lifetimes, which has been found by the inventors to compromise electron detection sensitivity.

The term “afterglow” may be understood as a persistent emission of light following the cessation of its stimulus, that is the incident electrons. An effect of this afterglow phenomenon is that electron flux on the scintillator member can result in a delayed rise to maximum light emission intensity. For instance, if the electron intensity incident on a scintillator member increases, the cumulative afterglow over all individual electron events generally takes a finite amount of time to rise and in accordance with that increased intensity. It will be understood that the term “modified image” generally refers to an improved or corrected image, specifically an afterglow-corrected image, that is an image corrected for luminescence persistence.

The first image data may be understood as being or comprising an image of at least a portion of the specimen, or sample of material. Typically, the image visualizes a portion or area on a surface of the specimen. The first image data may comprise one image or a plurality images. Typically, the first image data comprises a single image, with successive or multiple EBSD detector signal acquisitions, which give rise to afterglow effects in the acquired image, with those multiple acquisitions corresponding to the multiple pixels in that image. In some embodiments, however, the multiple acquisitions may correspond to multiple images.

The pixels, or values thereof, comprised by the first image data, or the first image data itself, may be understood as a data representation of visual information that may be obtained, stored, or transmitted in any form as is known in the art. That data may represent the monitored electrons in a variety of ways. In some preferred embodiments, the first image data may comprise virtual forward scattered diode (VFSD) image data. In such embodiments, a given pixel typically has a value representative of electrons emitted or scattered from a respective location of the plurality of locations.

The monitored electrons referred to above may be understood as those electrons being monitored, or having been monitored, by the EBSD detector. Typically, owing to the afterglow effects described earlier, in practice a pixel value represents not only the monitored electrons corresponding to that pixel (or rather to the part of the specimen image it represents), but also, to some degree, electrons incident on the scintillator member prior to those monitored electrons, by virtue of persistent luminescence caused by those earlier incident electrons. The method can advantageously reduce the degree to which those earlier incident electrons, or specifically the persistent luminescence caused by them, are represented in the pixel values.

The electrons being emitted from the specimen typically refers to those electrons being scattered, typically in a forward direction, owing to sample tilt, as described in greater detail later in this disclosure. It will be understood, particularly in the context of scattered electrons, that the electrons emerging from, or being emitted at, a given specimen location may refer to those electrons being emitted as a result of an electron beam impinging upon (or having impinged upon) that location, or having a centre or centroid of its beam spot located there, or at a beam spot location corresponding to that location. In this disclosure a beam spot may be understood as the area where the electron beam contacts the specimen surface. Typically, backscattered electrons emanate from an interaction volume within the specimen, the position of that volume typically being positionally related to, defined by, centred on, or having an epicentre located at, or more typically offset from, the location from which they are emitted from the specimen. In some preferred SEM arrangements, the tilt of the specimen surface relative to the direction of the impinging beam is such that an epicentre of an interaction volume for backscattered electrons is offset from the beam spot. This offset is typically greater at higher beam energies. In this disclosure, an analysis point or analysis location may refer to any of: a beam spot location, a location from which resulting electrons emerge, and a location related to one or more such locations. The electrons having been “emitted” from the specimen refers to electrons having emerged from or left the specimen, those emitted electrons having interacted with the specimen, for instance by being scattered or deflected thereby, or having been generated therein. That is to say, the emitted electrons may comprise any of a variety of different electron types, for example primary beam electrons scattered by the specimen, and free electrons generated within the specimen.

The said plurality of locations may be called monitored locations. The extent of that plurality of locations across the surface of the specimen may be understood as defining the said region, or may be within that region. The region typically corresponds to, or defines, or is the same as, the extent of the imaged part of specimen. That is, the region may correspond to or define the field of view of the image. In other words, the image field of view may be defined by the spatial extent of the plurality of locations.

In some implementations, the configured field of view may be different from the region on the specimen. For example, the field of view may extend beyond the specimen in at least one dimension. The extent of the region on the specimen may accordingly be defined, or limited, by the size, shape, or spatial extent of the specimen itself. In such cases, the SEM typically scans a configured field of view that extends beyond the specimen. It has been found that uncorrected images acquired under such conditions, where a configured field of view is only partly occupied by the specimen, results in particularly strong persistence artefacts in the acquired images. These are understood to result from the beam only impinging on the sample, and causing electron flux on the detector, for a part of its scan path across the field of view. Consequently, for parts of a scan path where the beam has passed off the edge of the specimen into an unoccupied part of the field of view, ‘ghost’ electron signals containing an afterglow of the preceding occupied part are present in the uncorrected image. These artefacts obscure the precise location of the specimen edge in the image, and so the method is particularly advantageous in these cases.

The electrons being emitted as a result of the electron beam impingement typically refers to those electrons resulting from that impingement, typically being scattered as a result thereof. The beam is preferably a focused electron beam. The beam may be defocused to some degree, which typically compromises spatial resolution in order to reduce a risk of electron beam damage in case of sensitive samples.

An EBSD detector may be thought of as an indirect electron detector. In use, electrons incident on the scintillator member of the detector cause the generation of photons therein. Those generated photons can then be monitored by an optical sensor. The scintillator member typically comprises a phosphor material. The term “phosphor” in this disclosure refers to a substance that exhibits luminescence, that is it emits light in response to incident particles such as electrons. The material may also be referred to as a phosphorescent material.

Generally, generated light that is attributable to a given incident electron is emitted over a period of time after that electron has been incident on the scintillator member. In other words, the light is not emitted by the scintillator instantaneously, but rather the emission follows a multi-exponential decay curve. The time dependence of the emitted light intensity may be modelled, in the aforementioned afterglow model, preferably as a sum of exponentials, typically with different decay constants. In the context of this disclosure, the time taken for the emission of light attributable to a given incident electron event to cease, or substantially so, may be referred to as a persistence lifetime.

The afterglow model may be provided as a set of data representing the time-dependence of the emitted light intensity in response to the scintillator being stimulated or energized. The model may thus be representative of afterglow characteristics of the scintillator member. In other words, the model may indicate, in particular for the purposes of the application of a correction algorithm, a response to electron absorption or incidence. Thus the model may characterise response decay, in particular a response decay curve. Typically, the model represents the characteristic as a multi-exponential decay curve, as noted above. Generally, the model may represent the characteristic as a function, such as an additive function, typically a sum or weighted sum, of one or more exponentials or other functions, typically with respective decay constants.

The generating of the corrected image preferably comprises applying any of a family of persistence correction algorithms as described, for example, in Hsieh J, Gurmen O E, King K F. “Investigation of a solid-state detector for advanced computed tomography”, IEEE Trans Med Imaging. 2000 September;19(9): 930-40. doi: 10.1109/42.887840, the entirety of which is incorporated by reference herein. The technique described therein involves a persistence characteristic of X-ray scintillators being modelled generally by a series of exponential terms, that is in an afterglow model. An accompanying algorithm, referred to as the HGK algorithm, typically employs the afterglow model to calculate iteratively the dynamic excitation state of an X-ray scintillator during an experiment, and the corresponding correction that may be applied to data acquired with that scintillator in order to remove persistence artefacts.

The inventors have found that such techniques may be advantageously adapted to address the phosphor persistence problems in EBSD imaging applications. Many variants of the HGK algorithm are known in the art, any of which could be applied with the present method by those skilled in the art.

The scintillator member of the detector is usually provided as a phosphor layer, or a phosphor screen, and is typically arranged in use to receive scattered electrons.

The EBSD detector typically employs a light sensor, that is a photodetector, such as a charge-coupled device (CCD) sensor or a complementary metal oxide semiconductor (CMOS) sensor. The method advantageously allows image data output by the light sensor to be corrected for the above-described persistence characteristics of the scintillator member from which the light sensor receives light.

In typical embodiments, the method may be a computer-implemented method. In particular, any one or more of the steps of generating the modified image, obtaining the first image, obtaining the afterglow model, and steps comprised by or comprising those steps may be computer-implemented.

Preferably the first image data is modified so as to be corrected. In particular, the said modification may be to compensate for, or reduce a contribution to the image (or more specifically to its pixel values) of, luminescence persistence of the scintillator member. It will be understood that generating a modified image comprises calculating the pixel values thereof.

The generating of the modified image may be understood as comprising calculating a contribution to the first image data, in particular to one or more pixel values thereof, of luminescence persistence. The generating of the modified image may accordingly comprise calculating modified image data, in particular one or more modified pixel values. The calculation may involve subtracting that calculated contribution from the first image data, or by otherwise calculating pixel values so as to reduce or remove that contribution.

Preferably, the aforementioned correspondence between the pixels of the first image data and the modified image comprises a one-to-one correspondence. Preferably, the first image data and the modified image have the same pixel resolution and/or a same size, and/or a same aspect ratio. In some embodiments, however, any one or more of these properties may differ between the first and modified images. For example, any one or more pixels of the modified image may correspond to, or be based on, the values of a set of two or more, typically adjacent or neighbouring, pixels of the first image.

The modified image may be thought of as a first modified image. In some embodiments, the method may involve generating a plurality of modified images, each of which may be based on corresponding data comprised by the first image data and the afterglow model. For example, the method may comprise generating a modified image based on, and corresponding to, each of a plurality of images comprised by the first image data, such as multiple EBSD images, or images obtained from different virtual diodes.

The calculation of a modified image pixel value is typically performed by way of applying an afterglow compensation algorithm to the first image data so as to reduce a contribution of the luminescence persistence characteristic in the modified image. This typically comprises an iterative calculation. The input to the algorithm typically comprises pixel values of the first image data, that is the uncorrected pixel values.

The afterglow model may be representative of a luminescence persistence characteristic of all or part of the scintillator member. In different embodiments, the model may represent a respective characteristic for each of a plurality of portions of the scintillator member. In such embodiments, where a plurality of portions may have their afterglow response characterised by the model, a represented characteristic of any one or more portions may be the same as, or different from, the representative characteristic of any one or more other portions.

In this context, a portion may correspond to a pixel of the detector, for example a portion of the scintillator that corresponds to a pixel of a light-sensitive detector component of the EBSD detector. A portion may correspond to a set or group of pixels, for example neighbouring or adjacent pixels.

A modified image may accordingly comprise a plurality of pixels each of which has a value calculated based on the value of a corresponding pixel of the first image data and a respective luminescence persistence characteristic comprised by the afterglow model. Such embodiments may also be understood as comprising a respective afterglow model being defined for each pixel. Similarly, calculation of image data values for a modified image may be performed for groups of pixels of any number or size.

A portion for which a respective local afterglow characteristic is modelled may, in some preferred embodiments, correspond to a predefined region of the scintillator member, or sub-regions thereof. Defining and using one or more such regions to produce respective electron images is described in greater detail later in this disclosure.

The method is particularly beneficial to implementations wherein an EBSD detector is used as a set of one or more backscattered electron detectors, and particularly VFSD techniques. Defining an arrangement of virtual detectors on an EBSD detector in this way allows images showing various combinations of topographic, atomic density, and orientation contrast to be obtained, and the present method allows the deleterious persistence effects to be mitigated. Accordingly, the EBSD detector may be used in a variety of ways in order to obtain the first image data.

In preferred embodiments, one or more regions of the EBSD detector is selected to function as a VFSD. A detector region or scintillator region defined as such may be used as an imaging sensor while the region on the specimen is scanned by the beam. When the beam impinges on a location on the specimen, the signal produced by or derived from the electron incidence in that region may be used to produce a pixel value to represent that location in the image, for example by any of integrating a signal acquired over or during the monitoring period, and combining signals acquired by pixels of an imaging sensor element of the EBSD detector.

Accordingly, in some embodiments, the first image data comprises a first image comprising the plurality of pixels, which may accordingly be called a first plurality of pixels, and each pixel of the plurality of pixels may correspond to, and have a value representing the monitored electrons incident on a first region of the scintillator member and emitted from, a location of the plurality of locations. The aforementioned monitored electrons refer to the resulting electrons monitored by the EBSD detector, and specifically those incident on the first region thereof. The region may correspond to the full area of the scintillator member, which is typically a scintillator screen. Typically, however, the detector is configured such that a collection region, or VFSD region, corresponds to a sub-area.

For each region of the scintillator, and correspondingly for each image acquired using that region, there may be a correspondence, typically a one-to-one correspondence, between pixels of the first image and analysis points on the specimen, as noted above. The analysis points may also referred to as acquisition points or monitored locations.

The EBSD detector may advantageously be used as a plurality of image sensors defined in this way. That is, in some preferred embodiments, the first image data further comprises a second image comprising a second plurality of pixels. Each pixel of the second plurality of pixels typically corresponds to, and has a value representing the monitored electrons incident on a second region of the scintillator member and emitted from, a location of the plurality of locations, with the first and second regions on the scintillator member typically being different. Typically, each sub-region is used to produce a separate image that can be used individually for analysis. However, in some images, data of any two or more images obtained from respective sub-regions may be used together, typically added together or subtracted from each other, to give a combined image or a difference image.

Typically, a plurality of sub-regions of the electron-sensitive detector element, that is the scintillator member or screen, are predefined. Preferably, the first and second regions are spaced apart on the scintillator, or are at least non-coincident, but any sub-region may partly overlap, contain, be contained by, or be contiguous with or adjacent to, another sub-region. Configuring sensor regions that are spaced apart is beneficial in that it facilitates the acquisition of images with complementary contrast and different contrast mechanisms. Preferably, any of the size, shape, relative position and absolute position of one or more sub-regions is user-configurable.

The first image data may comprise any number of further images corresponding to the respective further regions of the scintillator. In some preferred embodiments, the first image data comprises images obtained from a plurality of regions of the EBSD detector, each of which may operate to provide data as a VFSD. Data from multiple VFSDs may have respective weighting factors applied to them for the purposes of producing combined image data. A given VFSD image may be weighted differently to another image of the same specimen region.

Depending on the qualities of the scintillator screen, or phosphor screen, used in the method, it may be beneficial for the compensation for afterglow effects to reflect localised properties of the scintillator material around each sensitive region. Accordingly, in some embodiments, the first image data comprises a plurality of images. The plurality of images may represent, in the same way as defined above, the monitored electrons incident on a respective plurality of regions, that is including the first and second regions, of the scintillator member. It will be understood that the said plurality of images typically includes the first image and the second image, in addition to any further images obtained from any further regions defined on the detector.

Preferably the method further comprises providing a respective afterglow model for each of the plurality of regions. The method may comprise generating, for each of the plurality of regions, a respective modified image based on the corresponding image, that is corresponding to the region, or obtained based on electrons received at that region, and the respective afterglow model.

The method may comprise configuring or calibrating a respective afterglow model together with, or in accordance with, defining the regions on the detector. One or more regions may alternatively or additionally be predetermined. Any two afterglow models, or components of an afterglow model representing respective detector portions, may be the same or different from one another. Where two models are the same, they may refer to the same model component or model data. Each afterglow model may be representative of a luminescence persistence characteristic of a respective region, in the manner described above. Each modified image may comprise a plurality of pixels each of which has a value calculated based on the value of a corresponding pixel of the respective image data and a respective afterglow model, or a respective component of an afterglow model. The said corresponding image will be understood as being an image of the plurality of images, that is including the first and second images.

Some embodiments may involve collecting different types of image data alternatively or additionally to collecting data such as VFSD images. For example, the first image data may comprise one or more electron backscatter pattern (EBSP) images, and in such cases typically comprises a respective EBSP image for each of the plurality of locations. In some of these embodiments, the first image data comprises a first image representing the monitored electrons emitted from the plurality of locations.

In EBSP orientation mapping applications, for example, the region of the specimen may define a mapping field on the specimen. Thus, an image comprised by the first data may be an electron backscattered diffraction pattern image, and for such embodiments a pixel value of the first image data need not represent directly the generated particles at a respective location of the plurality of locations, but may represent multiple pixels. The plurality of pixels may correspond to, and represent the electrons emitted at, a first location of the plurality of locations. In typical EBSP embodiments, the values of the plurality of pixels may define or represent an EBSP image obtained by the EBSD detector. The first image data may comprise a plurality of EBSP images, wherein preferably each EBSP image corresponds to a respective location, preferably a different location, of the plurality of locations.

It is therefore envisaged that the method may be performed using and applying correction to both types of analysis and both types of data. For example, the first image data may be or comprise VFSD data, and can also involve obtaining and producing a further modified image or images based on second image data, which may be EBSP data.

Accordingly, the first image data may comprise a set of electron backscatter diffraction pattern, EBSP, images, each comprising a respective subset, typically distinct subset, of the plurality of pixels having values representing a respective subset of the electrons monitored by the EBSD detector emitted from the specimen at a respective location of the plurality of locations. In this context, a subset may be defined by the region of the detector, specifically the scintillator, on which the electrons in that subset are or have been incident. It may equivalently be defined by the region of the light-sensitive component at which light resulting from luminescence caused by the electrons in that subset was monitored or detected. It may be understood that, in a typical EBSD detector, a region of the light sensor may correspond to a region of the scintillator member. The method may comprise generating, for each of the set of EBSP images, a respective modified image comprising a plurality of pixels, each pixel having a value calculated based on the value of a corresponding pixel of the EBSP image and the afterglow model.

In some applications, luminescence persistence effects may be present when multiple EBSP images are obtained using the detector. These embodiments enable those effects to be mitigated.

Generally, the afterglow-corrected image generation process bases the calculation of the value for a given pixel on one or more pixel values in the first image data representative of monitored electrons incident on the scintillator member earlier than the monitored electrons represented by that pixel. Typically, the most recently acquired pixels preceding the acquisition of that same pixel are calculated as producing the most significant persistence contribution, which may be modelled by way of a greater weighting coefficient. In general, a persistence component of acquired data is determined by the afterglow model, which may indicate durations for which luminescence persists.

For example, in a pixel sequence ordered according to the acquisition of values using the EBSD detector, the correction procedure may use the value of preceding pixels. These are usually adjacent pixels, dependent on the scan acquisition path traversed by the beam on the specimen. In other words, for a large portion of pixels in an acquired electron image, earlier-acquired, that is preceding, pixels, can effectively be taken to indicate a scintillation or energization history that allows the luminescence persistence contribution to be calculated, and corrected for, to obtain a pixel value in the modified image.

However, in typical implementations, some pixels in the acquired first image are not preceded by a sufficient number of earlier acquired pixels, or by sufficiently recently acquired pixels, to provide a scintillation history for calculating or estimating the luminescence persistence contribution to it. In some cases, pixels are not preceded by any earlier acquired pixels, for example the pixel representing the first electrons monitored for a given image. Likewise, the first pixel acquired at the beginning of a row of pixels corresponding to a scan line in a scan pattern, for example where a raster scan pattern is traversed by the beam, prior to the first pixel in the row being acquired, a delay exists during which the electron beam spot on the specimen is travelling, or “flying back” from the distal end of the preceding row, and during which no pixel values are acquired for the image. Typically, no acquisition is performed during this time, which may be referred to as a flyback delay period, although it is envisaged that some data may be acquired for at least a portion of a flyback path in some embodiments. This can result in inadequate scintillation history information being provided for the correction algorithm.

Consequently, any electrons scattered from the specimen as a result of the beam impinging on the specimen during those delays, such as a pre-monitoring period, that is a period (typically a period of no monitoring) before the monitoring so as to acquire an image or a pixel begins, or flyback delays, are typically not represented in any pixel of the first image data, and so any afterglow from those electrons striking the scintillator cannot be accurately accounted for when using image pixels alone to provide the scintillation history.

Accordingly, some embodiments include performing an initialization step, in order to initialize the algorithm or maintain it in an initialized state, as part of calculating the modified image. The inventors have realized that initialization of the persistence correction algorithm, which is not required for conventional applications in medical scanning fields, is particularly beneficial when correcting for afterglow effects in images acquired by an EBSD detector in an SEM.

The application of an afterglow correction algorithm to an acquired electron image is most effective when applied to pixels for which the calculation can be based on an estimated, inferred, monitored, or deduced degree of excitation or energization in the scintillator member immediately prior to acquiring that pixel. It will be understood that typically the applying of such an algorithm obtains that energization information from one or more other pixels of the first image data, as alluded to above, on the basis that each pixel value includes a first, wanted component and a second, unwanted component.

The first component may be thought of as being attributable to electrons emitted from the relevant location on the specimen during the monitoring period for that location. In this disclosure, a monitoring period may be defined as the period of time during which the electrons emitted from the specimen at the location corresponding to the pixel of the modified image are monitored by the EBSD detector in particular, so as to obtain the value of the corresponding pixel or pixels of the first image data. Any of the start and end of a monitoring period may be defined, respectively, by the start and end of any of: the period over which the monitored electrons are incident on the scintillator member, the period for which the electron beam impinges upon the location, or is caused or configured to do so, and the period for which the imaging sensor of the EBSD detector (typically a CCD or CMOS sensor) monitors the signal so as to acquire the corresponding pixel value of the first image data. The said monitoring so as to obtain the value may be understood as referring to when the data or signal is output and/or used to produce the pixel value. Typically, the start of the monitoring period is defined as the time at which the monitoring so as to acquire a given pixel of the first image data begins. It is envisaged that the monitoring period for a pixel may be configured to coincide with a latter portion of the dwell period for (that is, the period during which the beam impinges on) the corresponding analysis point, so as to reduce the afterglow contribution to the monitored signal.

The second component may be thought of as being attributable to electrons emitted earlier, that is before the monitoring period, and/or from locations on which the beam impinged earlier. Thus, a value representative of the second component of a given pixel value in the first image data may be calculated or estimated based on the first component and/or the second component of each of one or more pixels acquired (that is irradiated by the beam, or monitored) before that given pixel. In this way, it may be considered that the image modification algorithm is kept initialized with data from previously processed or acquired pixels. However, the pre-acquisition and acquisition delay scenarios described above mean that, for those post-delay pixels, no suitable preceding pixels are available for the calculation of the requisite component values. It is therefore advantageous to initialize the corrective algorithm with an initialization data in order that a value of the second component for such pixels may be calculated.

In some preferred embodiments, therefore, the generating of the modified image comprises, for a pixel of the plurality of pixels, more preferably for each of a subset of the plurality, and more preferably still for each pixel of the plurality, scintillator state data being obtained in order to improve afterglow correction for that pixel or set of pixels. The obtaining of such data for initialization purposes is particularly beneficial when the data is used and applied to a pixel that corresponding to a location at the start (that is, impinged upon first) of a row in a scan pattern or scan path traversed during the acquiring of first image data. The scintillator state data may be advantageously used to obtain corrected values for a plurality of pixels acquired during an initial portion at the start of a monitoring period and having a duration corresponding to a persistence lifetime of the scintillator member.

The scintillator state data may be representative of energization of the scintillator member by electrons incident on the scintillator member prior to a monitoring period. The data may represent the energization at the start of the monitoring period. Obtaining scintillator state data is particularly valuable for the correction of pixels or locations that are not preceded sufficiently, or sufficiently recently, in acquisition by other pixels of the first image data to allow the energization state to be inferred. Preferred embodiments of the invention obtain this data so as to allow the afterglow model to be applied more accurately to those “initial” pixels. In other words, up-to-date scintillator state data prior to the start of a monitoring period enables artefacts to be reliably removed from the first pixels of that monitoring period.

The scintillator state data may be provided as electron exposure data, which may be called exposure history data, or irradiation history data. This data may be indicative of incidence of electrons over a period of time before the monitoring period, preferably as a function of time. Preferably it comprises or is derived from a set of irradiation history data that may be indicative of both an electron intensity value and a corresponding time value for each of a plurality of electron incidence events. From this, an energization state may be deduced, that is the energization state may be obtained or calculated based on the energization history over a period of time. That is to say, the state may be calculated or derived from the history. For example, the state may be calculated based on a sum or a weighted sum of history data.

The monitoring period may be defined simply as the time taken to acquire a pixel value from a monitored location, or to acquire the corresponding monitored electronic signal from the EBSD detector. The energization may be understood as the state of energization, or as a degree of energization. It may also be representative of an amount, quantity, or a level of energy imparted into the scintillator member, or accumulated therein. That is to say, the obtained data may represent the energy absorbed by the scintillator member by the said incident electrons, and may indicate an amount of energy, constituting or comprising energy that may or will be re-emitted during the monitoring period, that is as persistent luminescence. The above reference to the scintillator member may be understood as referring to the specific relevant region of the scintillator member or portion of it. For example, the scintillator state data may represent a given region corresponding to the VFSD, or a pixel or set thereof, in some embodiments.

The period prior to the monitoring period may be thought of as a preceding period or a pre-monitoring period. Preferably, the scintillator state data may be obtained so as to be indicative of an energization state of the scintillator member due to electrons incident thereon during one or more pre-monitoring periods, and it may be understood that each pre-monitoring period may be a period ending immediately prior to a monitoring period for a pixel or a set of pixels. For example, each may indicate energization at a start of a respective monitoring period.

Typically, a pre-monitoring period does not coincide with any monitoring period. For example, a pre-monitoring period may be immediately preceded by a monitoring period for an earlier-scanned part of the region, the start of that pre-monitoring period may then accordingly be defined as the end, or occurring immediately after the end, of that proceeding monitoring period. A pre-monitoring periods that immediately follows a monitoring period may be referred to as an inter-monitoring period.

For a plurality of monitoring periods preceded by pre-monitoring period, or preceded by a delay, for example when a location corresponding to the first-monitored pixel of an image or a scan line is monitored, the scintillator state data may initialize the algorithm so as to allow accurate correction for afterglow effects in spite of any acquisition delays or pauses. The monitoring period may be defined as the period of time during which the electrons emitted from the specimen at the location corresponding to the pixel of the modified image are monitored by the EBSD detector in particular, to as to obtain the value of the corresponding pixel or pixels of the first image data.

Advantageously, the value of a pixel of a modified image may then be calculated in accordance with the scintillator state data. That is, the method may comprise calculating, based on the energization state of the scintillator at the start of monitoring, a contribution to, or component of, the value of the pixel of the corresponding first image data, attributable to light emitted or monitored during the monitoring period as a result of energization of the scintillator member prior to that period. Accordingly, the method may comprise calculating the pixel value of the modified image such that the calculated afterglow contribution is removed therefrom, or at least reduced. The calculating in accordance with the scintillator state data may be understood as doing so in addition to performing the calculation in accordance with the afterglow model and the first image data pixel value.

A preferred approach for obtaining scintillator state data with which to initialize the algorithm following a delay or pre-monitoring period is to use data acquired directly by the detector, that is by acquiring one or more electron measurements from the EBSD detector. In some embodiments, therefore, the obtained scintillator state data is representative of electrons incident upon the scintillator member and emitted from the specimen at each of one of a set of one or more calibration locations as a result of the electron beam impinging upon the set of calibration locations prior to impinging on the location, that is the monitored location, corresponding to that one of the plurality of pixels.

The represented electrons referred to in the context of the scintillator state data may be understood as unmonitored electrons, that is electrons that are not monitored, in the sense that the signal representing the detection of those electrons is not deliberately acquired, at least for the purposes of obtaining the first image data. Nevertheless, those electrons will be understood as having been incident on the detector and so have an effect on the detection signal it outputs, that is on the first image data. That affect is advantageously mitigated by way of this additional data.

The said unmonitored electrons may be understood as being incident on the scintillator member during a pre-monitoring period that precedes a pixel value for a monitored location (that is one of the plurality of locations) being acquired, that is a period preceding a monitoring period. Preferably the scintillator state data represents incidence during a plurality of pre-monitoring periods preceding a respective plurality of monitoring periods.

The calibration locations may be called initialization locations. They may be understood as locations on the specimen the emitted or scattered electron signal from which is used to obtain initialization or calibration data. That is to say, they may be thought of as locations used to obtain the scintillator state data. Any one, more, or all of the calibration locations may be the same as or different from any one or more of each of the monitored locations, that is the additional measurements may or may not correspond to measurements used to acquire the first image data.

In some embodiments, the effects of inadequate initialization of the correction algorithm may be remedied by discarding one or more pixel values corresponding to one or more analysis points monitored within a persistence lifetime following commencing or recommencing acquisition. Accordingly, the modified image may exclude those pixels. Typically, the first locations to be monitored correspond to pixels at the periphery of an acquired image, and the method may comprise cropping the image data such that the modified image excludes those pixels. In such embodiments, the cropped or excluded monitored locations may be thought of as calibration locations, in the sense that they do not correspond to any pixel visualized in the modified image, but their pixel values may nevertheless be used in calculating values of pixels retained in the modified image.

It is possible in some embodiments to acquire the energization state information by taking additional measurements to those taken for generating the electron image, in particular by monitoring additional locations on the specimen. Accordingly, in some embodiments, each, or each of a subset of, the calibration locations may be different from each of the plurality of monitored locations.

The scintillator state data may be based on one location, or on a second plurality of locations. In some embodiments, such a second plurality is exclusive of the first plurality, that is each location in the plurality of calibration locations is not comprised by the first plurality of locations.

Typically, a monitoring period for a pixel commences concurrently or substantially so with the beam spot being configured to stop at an analysis location, that is an acquisition point. Any of the further locations, which may be thought of as previously scanned or irradiated locations, may thus be defined as a location of the beam spot prior to the monitoring period for a pixel, or prior to the arrival of the beam spot at the corresponding location to be monitored.

It will be understood, therefore, that in some embodiments, the obtained scintillator state data may be representative of electrons incident upon the scintillator member and emitted from the specimen at one or more further locations different from each of the plurality of monitored locations. These calibration locations may be within or outside the region of the specimen. Those electrons will be understood as being emitted as a result of the electron beam impinging on the one or more further locations prior to impinging on the location corresponding to that one of the plurality of pixels.

In typical embodiments, the first image data comprises pixel values that have been obtained by way of the electron beam having traversed the region of the specimen according to a raster pattern. That is to say, in typical embodiments, a raster scanning mode has been using in obtaining the first image data from the specimen in the SEM. Typically, the SEM is used to create an electron image for the specimen by scanning the beam across the specimen region in a pattern such as this, and the EBSD detector used to monitor locations along each scan line in order to obtain electron signals that may be used to compose a first image by arranging the pixels in a pattern corresponding to the order of the acquisition, that is the scan pattern. Such approaches typically involve acquisition pauses between successive scan lines, however. The start of the scan line being monitored following a flyback period may be referred to as acquisition resuming. Preferably, scintillator state data, which may be called initialization data since it may be used to initialize the algorithm at these stages, is obtained and used in the correction each time acquisition is resumed.

A flyback period may refer to the time taken for the electron beam to return from the end of one scan line to the beginning of the next scan line. Typically, this period is shorter than the persistence lifetime of the scintillator member and so electrons incident on the EBSD detector during the flyback period may energize the scintillator member so to cause persistent luminescence that contributes to the signal acquired by the detector at the start of the immediately subsequent scan line. A flyback period may accordingly be thought of as an example of a pre-monitoring period.

Typically, since the shortest flyback path taken by the beam is typically a diagonal path with respect to the array of scan lines, or points therein, each of the locations for which an electron signal is additionally monitored for initialization purposes, that is for obtaining the scintillator state data, is typically different from each of the monitored locations in any scan line. However, one or more calibration locations for which additional data is obtained may coincide with a monitored location in some embodiments. That is, a calibration location may overlap partly or wholly, or be the same as, a monitored location. It will be understood that a flyback path may partly or wholly retrace, coincide with, or intersect one or more scan lines, or may be separate therefrom.

In some embodiments, the first image data comprises pixel values obtained by way of an electron beam traversing the region of the specimen according to a raster pattern, wherein the set of calibration locations comprises one or more locations along a flyback path comprised by the raster pattern. The set of calibration locations may alternatively be defined by the scintillator state data comprising or being derived from data acquired by the EBSD detector during one or more flyback periods. The locations used to provide the scintillator state data may likewise be understood as being on the flyback path. Typically, a scan path comprises a plurality of flyback paths. One or more calibration locations may be defined on any one or more of such flyback paths. That is, the EBSD detector signal from any of those locations may be used to provide scintillator state data for initializing the algorithm.

In such embodiments, the obtaining of the scintillator state data may involve continuing to obtain data from the EBSD detector while flying back, such that the energization state of the end of the period, or at the start of monitoring of the next line, can be inferred. Data acquisition may continue during such a pre-monitoring period at the same rate, or a different rate from that of which it is acquired during a scan line being monitored. Any one or more additional calibration data points that may indicate energization, or more generally an energization history, of the scintillator member during the flyback period is typically beneficial to improving the correction applied to the subsequently acquired row, however.

In some preferred embodiments, the scintillator state data may be obtained by holding the electron beam in a fixed location during the period immediately prior to starting or resuming acquisition. With the electron beam maintained at a fixed location, the electron signal intensity will typically be constant, and only a single measure of this constant intensity is typically required in order to update accurately the persistence correction algorithm for the entire period in which the electron beam was positioned at that specimen location. Accordingly, in some embodiments, the scintillator state data is derived from, or comprises, data obtained from the EBSD detector, or electrons incident thereon, while the electron beam is being caused to impinge upon a first calibration location for a calibration time period, when the calibration time period is immediately prior to a monitoring period for a pixel of the first image data. The data obtained from the EBSD detector in this context is typically monitored in the same way as that used to obtain the first image data, albeit typically not monitored data in the sense that it is obtained for initialization purposes and is typically not used to obtain the first image data. The method may include performing the step of holding the electron beam at a location in this way, or it may involve acquiring data obtained from the step being performed as part of a previously performed acquisition process. In the former case, obtaining the scintillator state data may comprise causing the electron beam to impinge upon a first calibration location for a calibration time period, and monitoring electrons from the calibration location during that time.

Preferably, the calibration time period is greater than or equal to, that is at least as long as, a luminescence decay time period of the scintillator member. The luminescence decay time may be referred to as the emission duration, or the luminescence duration, and may be understood as referring to the time taken for the emitted light intensity from the scintillator member to decrease to a certain value after excitation. That value may be zero, or a predetermined non-zero value, and is typically a fraction of the initial value upon excitation, for example 10%, or more preferably 1% of the initial value. The luminescence decay time may be the same as the persistence lifetime described earlier. It may be indicated by the afterglow model, or otherwise obtained. The luminescence decay time may be obtained by measuring a luminescence decay curve for the scintillator. The decay time period may be provided for the scintillator member, or a respective period may be provided for one or more portions thereof, for example for corresponding to VFSD regions or regions corresponding to pixels or sets of pixels of the light-sensitive component. An appropriate decay time period may be used for comparison in accordance with the part of the EBSD detector used to obtain the scintillator state data.

These embodiments may accordingly be understood as having involved the beam being caused or configured to remain stationary at the calibration location. That is, in such embodiments the beam has been configured to maintain the beam spot at the calibration location for the entire calibration time period. This does not exclude the possibility of further calibration time periods, however. The calibration time period will be understood as being immediately before the monitoring period, or substantially so. That is, preferably there is no substantial interruption, gap, or delay between the calibration time period and the monitoring period. Reducing or eliminating the intervening time therebetween improves accuracy of correction using the scintillator state data, since the data may represent the energization state of the scintillator member more correctly.

The pixel of the first image data referred to in connection with these embodiments is typically the first pixel acquired in an electron image, that is the pixel to be monitored first. The pixel may be the first pixel of a set of pixels acquired following an acquisition pause, such as the flyback period, or a period between scanning successive lines or portions of the region, or between obtaining successive images. The calibration time period may be understood as being within, or occurring during, a pre-monitoring period immediately before the monitoring period. The monitoring period in this context may be understood as a monitoring period for the pixel, or for a corresponding monitored location.

In a preferred embodiment employing this approach, the electron beam is held at a calibration location that is chosen to be the location of the first acquisition point that follows an acquisition pause, for preferably substantially a persistence lifetime, immediately (preferably immediately or substantially so) prior to starting or resuming acquisition. Accordingly, the first electron image point acquired after starting or resuming acquisition may provide both a pixel value in the first image data, and a measure of the constant electron intensity that has been illuminating the screen for a period prior to starting or resuming acquisition, thereby providing scintillator state information. The persistence correction algorithm can then be accurately initialized using the obtained scintillator state data to reflect constant illumination at the intensity of the first pixel following the starting or resumption of acquisition.

Accordingly, in some embodiments, the first calibration location is a first location, typically the first monitored location, i.e. the first/earliest of the plurality of locations on which the beam impinges during the first image data acquisition. Preferably, a combined duration, that is a sum of durations, of the calibration time period and a monitoring period of the first location, that is the first monitored location, is greater than or equal to, that is at least as long as, a luminescence decay time period of the scintillator member. More preferably the calibration time period is at least as long as the luminescence decay time period. The combined duration may, for example, be a time period from the start of the calibration time period to the end of the monitoring period. Preferably, the calibration time period is at least as long as the decay period. The monitoring period of the first location may be understood as the period for which the first calibration position is monitored so as to obtain the first image data pixel value therefore.

In some embodiments, the scintillator state data further comprises data derived from, or obtained from data derived from the EBSD detector while the electron beam is being caused to impinge upon one or more further calibration locations for one or more respective calibration time periods. A calibration time period, preferably each calibration time period, may be prior, preferably immediately prior, to a monitoring period for a respective pixel of the first image data. Each further calibration location may be a respective first location, of the plurality of locations, on which the electron beam impinges during acquiring a respective portion of the first image data.

In embodiments involving one or more calibration locations, for each calibration location, preferably a combined duration of the respective calibration time period and a monitoring period of the respective first location, or more preferably the calibration time period itself, is greater than or equal to a luminescence decay time period of the scintillator member.

The said acquiring of a respective portion of the first image data may be understood as signal acquisition following an interruption or pause in acquisition, for example, a flyback period. In this disclosure, an interruption or pause in acquisition may be understood as referring to a period preceding an acquisition period (or between consecutive acquisition periods) that is sufficiently long for the scintillator state to change by a non-negligible degree. Specifically, this may refer to a pre-monitoring period that typically immediately precedes acquiring that portion, but during which the beam impinged on the specimen and hence during which the scintillator member is exposed to and energized by electrons. The respective portion may be understood as corresponding to a scan line in typical embodiments.

Typically, an inter-pixel period, that is a period between the respective monitoring periods of two adjacent pixels, is not sufficiently long and is not considered to be a pause or an interruption in this sense. Generally, the duration of an inter-pixel period is shorter than that of a pre-or inter-monitoring period, such as a flyback period, and is typically shorter by one order of magnitude. For example, a flyback period configured for a typical SEM may be approximately 100 μs. A typical inter-pixel period may be approximately 10 μs.

In some embodiments, the scintillator state data is obtained in accordance with the first image data and beam path data indicative of a path on the specimen traversed by the beam. Typically, obtaining scintillator state initialization data in this way, from first image data in combination with knowledge of a beam traversal path, is performed as an alternative to the above-described use of additional electron data. Obviating the need to acquire those further data points improves the speed with which the first image data can be obtained. However, it is envisaged that some embodiments might employ any of the approaches described herein for obtaining scintillator state data, in any combination. Such a combination may provide more accurate scintillator state data and thereby enhanced correction.

The method may comprise calculating the scintillator state data from the first image data and the beam path data, or the scintillator state data may be generated prior to the method being performed. The first image data referred to in connection with these embodiments may be understood as pixel values thereof corresponding to a subset of the monitored locations proximal to the path of the beam during one or more pre-monitoring periods. Beam path data may be available, for example, from the control system of the SEM. Beam path data may be understood as information or data that describes or represents the path, route, or trajectory followed by the beam. This data may comprise any one or more of: one or more coordinates of the position of the beam on the specimen, a direction of movement, and a change or deviation in a path, and any such information may be associated with data indicating a point in time during beam traversal. The beam path data may comprise data representing the movement of the beam spot on the specimen a function of time, that is it typically comprises temporal information associated with the traversal of the beam. For example, the data may comprise one or more values indicative of a rate or speed at which the beam traverses the beam path at one or more portions or locations along the path. In this way the data may indicate one or more time periods for which the beam impinges upon one or more locations, so as to allow an estimate of energization of the scintillator by resulting electrons to be calculated according to the time spent by the beam spot at or close to a location represented by a given known pixel.

The beam path data typically comprises an indication of a path portion within or at least coincident within the region. It may comprise a portion outside of the region.

Typically, the beam path data represents one or more portions of, or locations on, the path traversed by the beam during one or more pre-monitoring periods. Such knowledge of the beam path during a period preceding a monitoring or acquisition period, for example during flyback or prior to acquiring a given image or image portion, together with knowledge of the monitored intensity of electrons incident on the scintillator member and omitted as a result of the beam impinging on one or more respective locations on the specimen coincident with or proximal to the beam path, can be used to generate data representative of, or approximating or estimating, electrons incident on the scintillator member during that preceding period. That is, one or more monitored locations may be coincident with or proximal to the beam path, and therefore the pixel values of the first image data that correspond to such monitored locations can be used to calculate a value representative of an energization state attributable to the beam travelling over or close to those monitored locations. The beam path data may be calculated after the monitoring and optionally after the obtaining of the first image data. Likewise, the scintillator state data may be calculated at those times also.

It will be understood that some embodiments involve identifying which pixels of the first image data represent the analysis points over which, or close to which, a configured beam path passes over during a pre-monitoring period. Thus those acquired pixels may be used to perform initialization. However, in some embodiments a predetermined beam path may be configured or controlled for a pre-monitoring period such as flyback. That is, the beam may be controlled to pass over a predefined set of pixels during such a pre-monitoring period. For example, a flyback path may be configured such that the beam is caused to retrace a path that includes a known set of previously acquired points, or is caused to traverse a path including a set of points yet to be acquired, the data from which may be used in correcting the related pixel values.

In some embodiments, the obtaining or generating of the scintillator state data comprises calculating an estimated energization, or energization value, at the start of a monitoring period, of the scintillator member by electrons emitted from the specimen as a result of the electron beam impinging on the beam path, or a sample location, or a second plurality of locations, and incident on the scintillator member prior to the monitoring period, based on, for each of one or more pixels of the first image data, or for a set or one or more of those pixels, the pixel value and a positional relationship between the corresponding location on the specimen and the beam path.

Advantageously, the excitation state of the scintillator member may be estimated from data acquired in the electron image, with no additional measurements required prior to pausing or resuming the electron image acquisition. The time-dependent location of the electron beam during a pre-monitoring period such as an acquisition pause, or a period prior to starting acquisition, can be estimated or modelled, according to the beam path data. Typically, the position or path of the beam prior to or starting or resuming acquisition is generally contained within or lies close to the electron image field of view. Estimates or models of the beam position, combined with electron image pixel intensities at or close to those locations, may accordingly be used to calculate the time-dependent irradiation of the scintillator member during an acquisition pause or prior to the start of acquisition.

An estimated energization may be calculated for each of one or more monitoring periods, that is the estimating the energization state prior thereto. Accordingly, the estimated energization may relate to the electrons emitted, and in particular backscattered, from the sample as a result of the electron beam impinging on a portion of the beam path traversed during the pre-monitoring period. The one or more locations on or along the beam path, which may be referred to as beam path locations, may be the same, different, or coincident with any of the monitored locations.

The calculating of the estimated energization may be performed directly or indirectly, for example may be based on the first image data by virtue of being based on the modified image pixel values derived therefrom.

The calculation may be based on the positional relationship, for example a weighted function. Typically, in such a function, a weighting coefficient applied to a pixel value for a monitored location may be positively dependent on a proximity of the monitored location to the beam path. Since a closer proximity typically signifies a more similar emitted electron response from the specimen material, such a function may accurately estimate energization.

In a simple implementation of this approach, prior to starting the acquisition of a line of an electron image, the standard scan pattern of the electron beam may cause the beam to be located in the vicinity of the first acquisition point for that line for a period of time. The measurement taken at this first monitored location, or acquisition point, in the scan line may then provide a reasonable estimate of scintillator irradiation prior to starting or resuming image acquisition, and may be used to provide an estimate of energization, without requiring a pause in beam movement or acquisition in any specific location as with the previously described embodiments involving calibration locations.

Typically, afterglow-compensated images are generated as part of an SEM analysis procedure, preferably in real time. Accordingly, the method may further comprise, causing the electron beam of the scanning electron microscope to impinge upon the plurality of locations within the region of the specimen; monitoring, using the EBSD detector, the resulting electrons emitted from the specimen at the plurality of locations and incident upon the scintillator member of the EBSD detector so as to obtain the first image data.

However, a modified image may, in various embodiments, be generated at different times, which may be concurrent with acquiring first image data using the EBSD detector in the SEM, or after the acquisition. In post-acquisition implementations in particular, the method typically comprises obtaining temporal data representative of one or more time intervals between (typically successive) acquisitions by the EBSD detector. A time interval in this context may be a period between acquiring electron signals corresponding to, and used to obtain values for, two respective, typically adjacent, pixels of an image. Alternatively, a time interval may occur between acquiring electron signals corresponding to entire EBSP images acquired in a mapping sequence for example, or corresponding to electron signals derived at different times from electrons monitored at a given location on the detector or scintillator member.

This may be beneficial as the afterglow exhibited by the detector is typically a function of time. Temporal data may indicate acquisition timing, and so the generating of the modified image using the afterglow model may utilise that timing information to model or calculate, or importantly to compensate for, the luminescence persistence of the detector scintillator member during the acquisition and over those time intervals.

Any of the electron beam scanning modes described herein may be employed in obtaining the first image data. It will be understood that this need not be performed as part of the method according to first aspect, and may have been performed prior to performing the method. In such cases, the scanning mode generally defines certain qualities or characteristics in the first image data that give rise to the advantages described herein.

It may be understood that, in embodiments where acquisition using the detector in the SEM is performed as part of the method, or at least partly concurrently with the generating of modified images, temporal data may in effect be obtained by virtue of the acquiring timing being known, predetermined, measurable, measured, or signalled. Moreover, the temporal data may be obtained concomitantly with the operation of the instrument and detector, or may be available from a controller of an electron microscope and/or detector control system for instance.

In such embodiments, the first image data may be understood as the first image data that comprises a plurality of pixels having values representing the monitored electrons, that is the resulting electrons monitored by the EBSD detector. In some embodiments, the method further comprises causing the beam not to impinge upon the sample, or precluding the beam from impinging upon the sample, or substantially doing so, during a blanking period prior to the monitoring period, wherein a duration of the blanking period is greater than or equal to a luminescence decay time period of the scintillator member. In some embodiments, the method may comprise partly or wholly obscuring the beam so as to reduce or preclude the beam impinging upon the specimen.

Deactivating, or blanking, the beam for a period prior to starting or resuming acquisition may be advantageous. The blanking period may be understood as a pre-monitoring period in such embodiments. Preferably, the blanking period is immediately prior to the monitoring period. However, the reduction in energization caused by the blanking may nevertheless remain advantageous if a delay between an end of a blanking period and the next monitoring period is significantly shorter in duration than the luminescence decay time period of the scintillator member. For example, the beam may impinge upon the sample for a post-blanking, pre-monitoring period that is one or more orders of magnitude shorter than the luminescence decay time period. Ceasing irradiation of the screen for the period in which the beam is blanked causes the energization, or the energy accumulated in the scintillator member, to decay and thereby reduces subsequent luminescence persistence. Therefore, scanning in this mode allows the persistence correction algorithm to be updated to reflect that no further excitation has occurred in that period. Blanking the beam for a period at least equal to the length of the acquisition pause, or a persistence lifetime, which may be understood as the time taken for most of any energy stored in the screen to be released and persistence emission to drop to substantially zero, which is typically in the order of several milliseconds, whichever is shorter, enables initialization of the persistence correction algorithm for a new acquisition. Thus the duration of the blanking period is preferably greater than or equal to the luminescence decay, thereby allowing the luminescence to cease.

With typical implementations of an afterglow correction algorithm, if the scintillator member is not energized before the first pixel is monitored, owing to the beam being blanked immediately beforehand, for example, no correction needs to be applied for that pixel. The irradiation history with which the algorithm is to be kept initialized can begin with the irradiation arising from that first pixel acquisition, and subsequently acquired pixels may be corrected. Typically, in the absence of an indicated energization level for the start of a monitoring period, the algorithm performs the correction on the basis that the scintillator member is not energized at the start of that monitoring period. In other words, typical correction implementations treat a null energization value as a zero value. Blanking the beam can therefore render this assumption accurate, and thereby render the afterglow correction more accurate, in the case of a scan procedure involving pre-monitoring periods that give rise to inadequate irradiation history in the first image data itself.

If the beam is blanked, so as to achieve a non-energized state at the start of a monitoring period, that state may in some embodiments be explicitly indicated or signalled to the algorithm by way of scintillator state data, to initialize the calculation with an explicit zero value. Otherwise, this indication may be implicit, and the algorithm may accordingly be configured such that a zero energization is assumed in the absence of a signal non-zero energization state.

The above-described approach may be implemented in embodiments wherein the correction is performed post-acquisition, that is wherein the monitoring does not form part of the method. In such cases, preferably the scanning mode data is provided indicating that the beam has been blanked.

A further advantageous approach to applying afterglow correction is to minimise the number of inter-monitoring periods, or acquisition pauses. This may be achieved by way of acquiring the electron image in a scanning order that does not induce such pauses. Unlike with a raster scan pattern, a continuous pattern such as a spiral or serpentine pattern does not include a flyback delay. Instead, when a beam reaches an end of a scan line, it steps immediately down to the next scan line of the image, and scans that line in the reverse direction to the previous line. By eliminating such flyback delays, the need to initialize the correction algorithm with scintillator state data for each line may be obviated.

In some preferred embodiments, the electron beam is caused to impinge upon the plurality of locations according to a continuous scan pattern. Such patterns may be understood to be continuous in the sense that the electron beam traverses the region without interruption, without the need for pauses or flyback periods between scan lines or portions of the image that are necessary in, for example, raster scanning.

These scan modes may be defined alternatively as scanning paths, patterns, or modes in which, for all, or at least a portion of the region, or the traversal path defining or corresponding to it, no delay, pause, or pre-monitoring period between any two successive monitoring periods, that is between the end of a time during which of a first of two successively monitored locations is monitored and a beginning to monitor the immediately subsequently monitored location, exceeds a maximum value. In some embodiments, the scan pattern chosen may be at least partly continuous. For example, it may comprise a number of pauses or flyback periods less than a predetermined number, for example, 3, 2, or 1.

Although advantageous for mitigating the effects of inter-monitoring periods, typically, the choice of scan pattern does not in and of itself remove the issue of persistent luminescence caused by electron incidence prior to the first image point being acquired, for which initialization using scintillator state data according to any of the above approaches is preferably applied.

According to a second aspect of the invention, there is provided a system for obtaining a modified image of a specimen in a scanning electron microscope, the system comprising: an electron backscatter diffraction, EBSD, detector and a processor, the system being configured to: acquire first image data, the first image data comprising a plurality of pixels having values representing monitored electrons emitted from the specimen, at a plurality of locations within a region thereof as a result of an electron beam of the scanning electron microscope impinging upon the plurality of locations, and incident upon a scintillator member of the EBSD detector, and generate a modified image comprising a plurality of pixels each having a value calculated based on the value of a corresponding pixel of the first image data and an afterglow model representative of a luminescence persistence characteristic of the scintillator member.

Typically the EBSD detector is configured to monitor the electrons. The processor, which may be provided as one or more processors, is typically configured to perform any of the steps of: receiving a signal from the detector, receiving the first image data therefrom, and generating the modified image. A processor of the system may be configured to perform any of the steps described in relation to the first aspect.

A processor may be understood as a processing unit, typically capable of executing instructions or performing arithmetic or logical operations. In particular the processor may be configured to perform any of the method steps described in relation to the first aspect. The processor may comprise any one or more of a central processing unit (CPU), a graphics processing unit (GPU), a digital signal processor (DSP), and a field-programmable gate array (FPGA), or any other type of processor as is well known in the art.

A processor, or a computer device comprising a processor, may be comprised by the EBSD detector, or may be provided separately, and be configured to be in data communication, directly or indirectly, with the detector, at least when in use. A processor or computer device of the system may be comprised by, or comprise, a control device configured to control any one of more of: the EBSD detector, the electron beam, a sample stage or holder for holding the specimen in use, the SEM, and any component thereof.

The system is particularly advantageous when configured to acquire electron image data using a VFSD technique. Typically, therefore the system is configured such that: one or more virtual detector regions of the scintillator member may be defined, whereby the first image data comprises, for each of the one or more virtual detector regions, a first image comprising a respective plurality of pixels, each pixel which corresponds to, and has a value representing the monitored electrons incident on the virtual FSD region and emitted from, a location of the plurality of locations.

According to a third aspect of the invention there is provided a scanning electron microscope comprising a system according to the second aspect.

According to a fourth aspect of the invention there is provided a computer program product comprising instructions which, when executed by a computer, cause the computer to carry out the method of the first aspect. Typically, the computer program product is configured such that a computer or processor thereof carrying out the method acquires the first image data, whether from a previously performed acquisition process carried out in an SEM, or as part of that acquisition process, and performs the generating of the modified image by performing the afterglow correction algorithm in the manner described above.

### BRIEF DESCRIPTION OF DRAWINGS

Examples of the present invention will now be described, with reference to the accompanying drawings, in which like features are denoted by like reference signs, and in which:

FIG. 1 is a flow diagram showing a first example method of obtaining a modified image of a specimen in a scanning electron microscope according to the invention;

FIG. 2 is a rendering of an example system for performing the example method according to the invention;

FIG. 3 is a photograph of an example system for performing the example method according to the invention;

FIG. 4 shows a first image and a modified image acquired in the first example method according to the invention;

FIG. 5 shows a section of a modified image acquired in the first example method according to the invention;

FIG. 6 is a modified image acquired in the first example method according to the invention;

FIG. 7 is a flow diagram showing a second example method of obtaining a modified image of a specimen in a scanning electron microscope according to the invention; and

FIG. 8 is a schematic diagram of first and second example scanning electron microscope scan patterns for example methods according to the invention.

### DETAILED DESCRIPTION

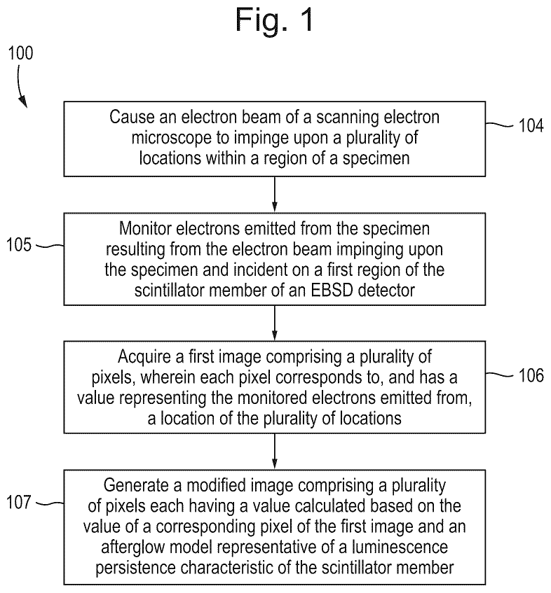

With reference to FIGS. 1-8, examples of methods according to the invention are now described.

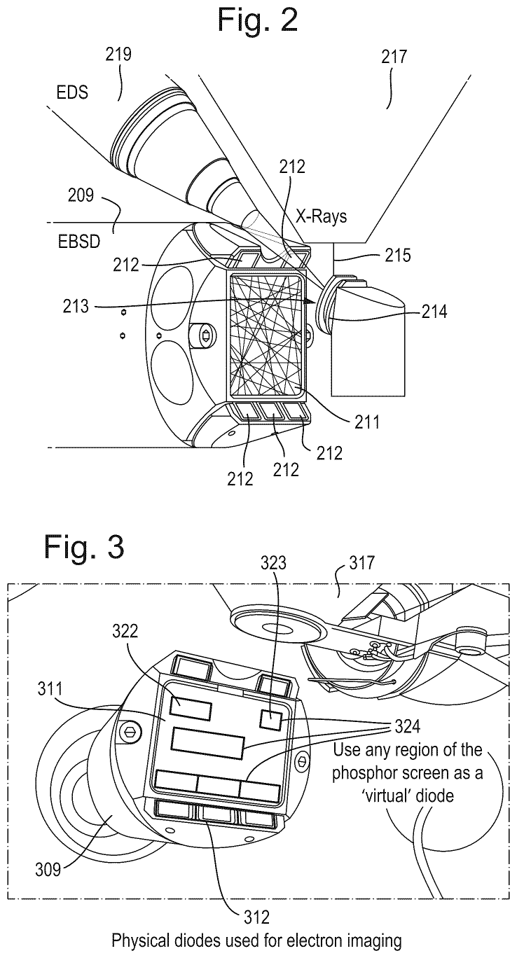

A first example method 100 is illustrated in FIG. 1 and is performed using a system as shown in FIGS. 2 and 3. An EBSD detector 209 employing a scintillator member in the form of a phosphor screen 211 is mounted to an SEM (not shown). The detector 209 further comprises a light-sensitive imaging detector in the form of complementary Metal Oxide Semiconductor (CMOS) sensor and a suitable optical system (not shown) for monitoring light emitted by the phosphor screen in response to incident electrons. The detector 209 comprises a set of forescatter diodes (FSD) 212 mounted above and below the phosphor screen 211, which may be used to generate microstructure images of the specimen before collecting EBSD data.

A specimen 213 is arranged in a typical EBSD experiment geometry, with the specimen being mounted on a sample holder 214 approximately level with the detector and tilted to a high angle of around 70° relative to the direction of the incident electron beam 215 that is directed onto the specimen from the final polepiece 217 of the electron beam assembly of the SEM. The system shown in FIG. 2 additionally includes an energy dispersive X-ray spectrometry (EDS) detector 219, which is not discussed further in this disclosure.

The persistence characteristic of the phosphor screen 211 is measured and modelled prior to performing the method. The measurement is preferably carried out only once for a given phosphor screen, or for a given manufactured batch of phosphor. This measuring and the generating of a persistence model or afterglow model may be performed in production, or at the time of installing the detector, which may account for potential variations between manufactured batches. The properties of the phosphor are not expected to alter significantly over time or with use. However, if the afterglow model, which may also be called a persistence model, for a given screen is not performing adequately, it is possible to re-measure the phosphor characteristics after detector install and generate an updated model accordingly.

For this example method, it is generally sufficient to model the properties of the phosphor screen as being uniform across the whole screen. That is, it is assumed that localized phosphor variations or material defects have a negligible effect on local luminescence persistence properties, and a single afterglow model is used for the persistence correction of all acquired first image data. However, in variants of the method, respective, and potentially different, persistence models may be assigned to different regions or even different pixels of the imaging detector, reflecting the localised properties of the phosphor coating around each pixel.

The persistence model representative of a luminescence persistence characteristic of the phosphor screen is typically formed by subjecting the detector to a rapidly switched on/off electron signal, measuring the detector response, and fitting this response to a model of phosphor persistence. A preferred example of such a model and its use for persistence correction, in the field of X-ray computed tomography (XCT) scanners, is described in Hsieh J, Gurmen O E, King K F. “Investigation of a solid-state detector for advanced computed tomography”, IEEE Trans Med Imaging. 2000 September;19(9):930-40. doi: 10.1109/42.887840, the entirety of which is incorporated by reference herein. That model is referred to as the ‘HGK’ model, and is employed in the image correction step of the present example method.

The present example method uses virtual diode imaging. In such experiments, an area, or each of a plurality of areas, of the phosphor screen of the detector are selected by the user to act as a virtual diode. Each virtual diode may be as large as the whole detector screen, or as small as a single pixel, and there is flexibility over the size, shape, and position of these virtual diodes on the screen. Each virtual diode comprises a contiguous subset of pixels in the pixel array of the imaging sensor. FIG. 3 illustrates this principle. A first region 322 of the phosphor screen 311 is defined as a first virtual diode, and is used to acquire electron imaging data from the specimen similar to data obtainable using the physical diodes 312. With virtual diode techniques it may likewise be advantageous to obtain imaging data using multiple separately defined sensors. A second region 323 corresponds to a second virtual diode, and a plurality of further virtual diode regions 324 are similarly defined. Each screen region may be referred to as a virtual diode region. Configuration of the virtual diode arrangement for the purposes of the present example method is effected by defining a plurality of corresponding regions of the CMOS sensor, or groups of pixels thereof, each region or group being arranged to detect light emitted by a respective screen region 322-324. Those CMOS pixels may be thought of as belonging to the corresponding screen region.

At step 104, the electron beam 215 is scanned over, that is caused to impinge upon, a plurality of locations on the specimen 213 which, in the present example, are configured as a regular, equally spaced grid or array of points. The array of points to be scanned is configured to align with a region of interest on the specimen, such that the locations are within the region. At each specimen point to be monitored, the beam pauses for a pre-defined acquisition period, during which electrons impinging on the specimen are scattered from its surface and are incident on the phosphor screen 211.

At step 105 the incident electrons in each virtual diode region 322-324 of the screen 311 are monitored. In each pixel belonging to a virtual diode region, the electron signal integrated over the acquisition period is measured, and the electron signal in all pixels belonging to a virtual diode region is summed to give the total electron signal acquired in that virtual diode. The total virtual diode signal at an acquisition point in the electron scan is used to form, that is obtain a value for, a pixel of a first image, namely an electron image of the region of interest, at step 106. Thus each pixel corresponds to, and has a value representing the monitored electrons scattered from, a location of the plurality of locations. A separate electron image is generated in this way from the signal output by each virtual diode.

Due to phosphor persistence, the raw virtual diode detector readout from the Nth point to be monitored while scanning the electron image will contain contributions from the virtual diode signal measurements at the (N-1)th, (N-2)th, . . . acquisition points that immediately preceded it in the scanning order. Pixel artefacts caused by these contributions are typically described as ‘ghosts’ of preceding pixels.

At step 107 the phosphor persistence model, which in the present example is the HGK model, is used to calculate the contribution that these previous electron signals incident on the detector will be making to the current detector readout. The calculation is performed using an iterative algorithm (also published with the HGK model) that is updated for each acquisition point. This persistence contribution is subtracted from the raw detector readout, that is the first image data, at the Nth point in the image to give a corrected virtual diode signal at this point. This corrected signal is a significantly improved representation of the actual electron signal that was incident on the virtual diode region of the phosphor screen during the Nth acquisition.

By modifying the electron image in this way, using the persistence-corrected virtual diode signals, the resulting modified image shows significantly improved resolution.

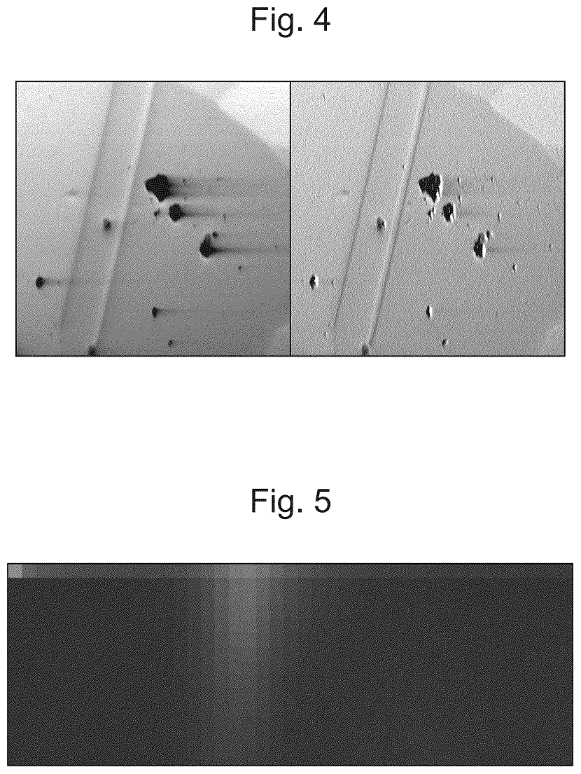

FIG. 4 shows a comparison of a first image (left side) acquired using a FSD technique and a modified image (right side) obtained by applying phosphor persistence correction to the first image according to the example method.

As illustrated by the first image, using a phosphor screen of an EBSD detector as a virtual diode for electron imaging in an SEM results in images that display streaking along the path of the scanned electron beam (usually horizontal), and poor resolution. These artefacts result from phosphor persistence and limit the viability of virtual diodes as an electron imaging solution.

The correction applied at step 107 addresses this problem by calculating and subtracting the phosphor persistence contribution from all virtual FSD signals output by the EBSD detector. It can be seen from the comparison of FIG. 4 that pixel values in the modified image no longer contain significant contributions from the previously acquired points in the image, and that the modified image exhibits reduced streaking artefacts. The algorithm is sufficiently fast to be applied to data output from the detector in real time if required. In the present example method, the correction is applied as the image data is collected within the SEM. However, it is also envisaged that the method can be applied to historical data previously captured using a known phosphor screen, providing that captured image data as in step 105 and applying the correction as in step 107.

Whether it is employed during or after acquisition of the first image data, the afterglow correction technique significantly improves the viability of virtual diode imaging techniques as an electron imaging solution.

Further improvements may be achieved by addressing the issue of the afterglow correction algorithm not being adequately initialized for certain parts of the acquired image.

When acquiring electron images in the SEM, image acquisition typically starts with the phosphor screen in an irradiated state: the electron beam is active, causing the screen to be exposed to electrons, both while the operator is finding a region on the specimen from which to acquire an electron image, and while the detector and electron beam are initialized immediately prior to the start of the image acquisition.

Further, depending upon the scan pattern used, the process of acquiring an electron image typically includes a series of short acquisition pauses. This occurs, for example, when using a raster scan pattern to acquire the electron image, which is a typical scanning mode employed in SEM operation. After the final point of an electron image scan line has been acquired, the electron beam must ‘fly back’ to the location of the first point of the next line. This takes a finite time, and during this pre-monitoring period the detector is not acquiring, that is it is not monitoring incident electrons. The exact duration of this pre-monitoring or inter-monitoring period depends on the microscope and is known from a calibration procedure performed at detector install.

Such periods of unmonitored electron incidence are problematic when using conventionally configured persistence correction algorithms, including the HGK algorithm. With known implementations of such correction procedures in the field of medical scanning, data acquisition begins with a detector that has not been recently irradiated, and all measurements subject to persistence correction are equally spaced in time, with no delays or pauses in acquisition between them. As such, these known applications of afterglow correction algorithms do not suffer from inadequate initialization or any unwanted image artefacts arising therefrom, since in those applications the algorithms can accurately mitigate the effects of persistence without miscalculated contributions of persistence.

Conversely, in the field of VFSD imaging using an EBSD detector as implemented according to the first example method, unknown or unaccounted-for irradiation of the screen during these pre-and inter-monitoring gives rise to large artefacts introduced by the algorithm. These are visible on the first line of the image, owing to a lack of initialization of the algorithm before the first point was acquired, and in the first few points of each line, owing to inadequate initialization for flyback periods between scan lines.

A first example image artefact is shown in FIG. 5. A ‘burn-in’ effect is visible over the first several points of the electron image, whereby the HGK algorithm, in the absence of information about the irradiation history to which the screen was subjected prior to the first point being acquired, or the resultant energization state of the screen at the start of acquisition, causes a ‘comet-trail’ artefact. In other words, the persistence correction algorithm has not been initialized with any screen irradiation history, and so the algorithm assumes that the experiment begins with a phosphor that has not been irradiated.

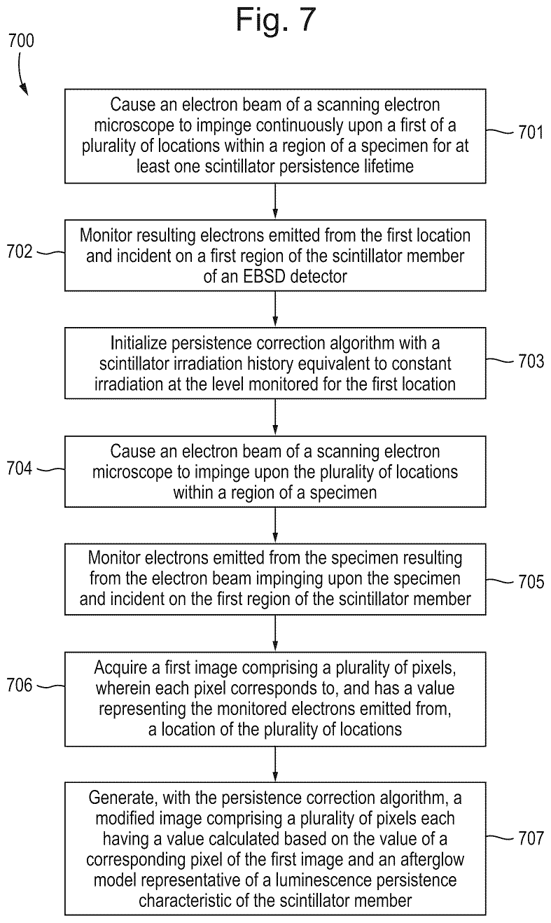

Initializing the algorithm prior to starting electron image acquisition has been found to address this issue. This involves measuring, calculating, or estimating the phosphor screen's recent irradiation history immediately prior to starting or resuming acquisition after a pause. FIG. 7 shows a second example method similar to that of FIG. 1 and additionally including a pre-acquisition initialization step.

Prior to starting the acquisition of electron image data in step 704, the phosphor persistence algorithm is initialized. At 701, the electron beam is held at the location of the first electron image point to be monitored during acquisition for at least one persistence lifetime immediately prior to starting the electron image acquisition. The resulting scattered electrons are monitored at 702, and a single virtual FSD measurement is acquired for each virtual FSD in this location.

The persistence correction algorithm is initialized at 703 with a phosphor irradiation history equivalent to constant irradiation at the level measured by that single measurement.

The properly initialized algorithm can then be applied to the image data acquired at 706 such that artefacts such as that seen in FIG. 5 are reduced or removed.

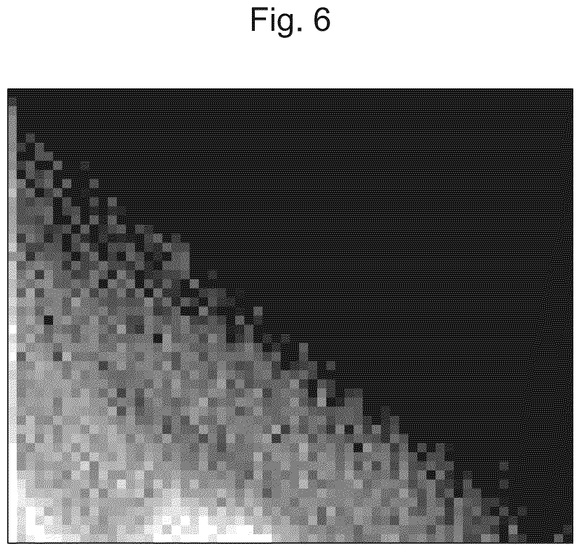

However, in addition to the effect seen at the earliest acquired pixels of a corrected image, the first example method typically also results in unwanted correction artefacts arising from inter-monitoring periods, as noted above. An example of such an effect is shown in FIG. 6, as a grey-level discontinuity in the first few pixels in each row. This is seen when using the first example method and acquiring the electron image using a scan pattern with a flyback delay, such as a raster pattern. This is caused by not accounting for the flyback delay in the persistence correction algorithm; that is, correcting the first pixel of each row as if it were acquired immediately following the last pixel of the previous row, and thus subtracting an inaccurately calculated afterglow component of the pixel value.

In preferred variants of the second example method, the persistence correction algorithm is also properly initialized for the start of each row. That is, an initialization procedure is also performed after any acquisition pause, such as following a flyback delay. It has been found that performing initialization for the resumption of acquisition following each delay, or inter-monitoring period, results in these discontinuity artefacts no longer being visible in the modified images.

For both of the artefact types exemplified in FIGS. 5 and 6, the root cause is the same: the algorithm is not provided with adequate information indicative of the recent irradiation history of the phosphor screen, either before acquisition starts, or after an acquisition pause, so the persistence correction cannot be accurate.

Variants of the second example image may use, additionally or alternatively, different techniques to obtain and initialize the correction algorithm with the irradiation state of the screen.

In a variant, a series of virtual FSD measurements are made immediately prior to starting or resuming acquisition of the electron image, these measurements covering a time period of at least one persistence lifetime and used to initialize the persistence correction algorithm with the irradiation history of the phosphor screen immediately prior to starting/resuming acquisition. Maintaining the beam spot at the first imaging point and accordingly initializing the algorithm as in steps 701-703 of the method is a preferred example of this approach, although a set of one or more such calibration VFSD measurements may be made at any suitable locations.

In another variant, the electron beam is assumed to have been located in the vicinity of the first electron image point to be acquired after starting or resuming acquisition of the electron image, and the pixel intensity measured at this first point is assumed to be representative of the phosphor irradiation intensity for at least a persistence lifetime immediately prior to starting or resuming electron image acquisition.

Variants of the method may use any one or more different initialization methods in any combination at acquisition start and when resuming acquisition after a pause.

In a third example method, the issue of inadequate initialization is addressed by the alternative approach of blanking the electron beam. In this example, the SEM beam is switched off, or otherwise caused to cease impinging on the specimen for a phosphor persistence lifetime immediately prior to starting or resuming acquisition of the electron image. The persistence algorithm may then be initialized to reflect the phosphor screen having zero excitation during the period in which the beam is blanked. Typical implementations of the algorithm assume a zero excitation state at the start of an acquisition run, and therefore the third example method enables the correction to be accurately calculated for the initial pixels of images or scan lines on that basis.

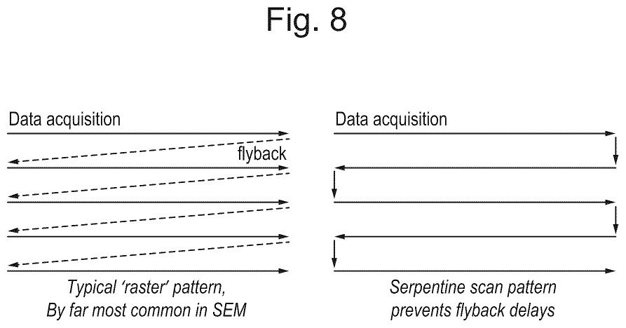

A fourth example method involves using a specific scan pattern type when acquiring the electron image data, as illustrated at FIG. 8. In particular, instead of a raster pattern (left side), the fourth example method uses a scan pattern not having a flyback delay, such as a serpentine scan pattern (right side), to acquire the electron data. Consequently discontinuities of the type shown in FIG. 6 are not produced by the correction algorithm.

In addition to virtual diode imaging methods, phosphor persistence correction according to the foregoing example methods may be used in other EBSD applications; in particular, EBSD crystal orientation/phase mapping. For crystal orientation mapping, the persistence correction model and algorithm can advantageously remove persistence artefacts from full electron backscatter diffraction pattern (EBSP) images. Such methods may simply treat each pixel of the diffraction pattern image as a separate region, or virtual diode, for persistence-correction purposes). This has been found to be beneficial in experiments involving low-speed, high-signal data acquisition, and with specimen regions that include some specific physical features, such as voids or edges.

1. A method of obtaining a modified image of a specimen in a scanning electron microscope, the method comprising:
acquiring first image data, the first image data comprising a plurality of pixels having values representing monitored electrons emitted from the specimen, at a plurality of locations within a region thereof as a result of an electron beam of the scanning electron microscope impinging upon the plurality of locations, and incident upon a scintillator member of an electron backscatter diffraction, EBSD, detector; and
generating a modified image comprising a plurality of pixels each having a value calculated based on the value of a corresponding pixel of the first image data and an afterglow model representative of a luminescence persistence characteristic of the scintillator member.

2. The A method according to claim 1, wherein the first image data comprises a first image comprising the plurality of pixels, and wherein each pixel of the plurality of pixels corresponds to, and has a value representing the monitored electrons incident on a first region of the scintillator member and emitted from, a location of the plurality of locations.

3. The method according to claim 2, wherein the first image data further comprises a second image comprising a second plurality of pixels, and wherein each pixel of the second plurality of pixels corresponds to, and has a value representing the monitored electrons incident on a second region of the scintillator member and emitted from, a location of the plurality of locations, wherein the first and second regions of the scintillator member are different.

4. The method according to claim 3, wherein the first image data comprises a plurality of images representing the monitored electrons incident on a respective plurality of regions of the scintillator member, and wherein the method further comprises:
providing a respective afterglow model for each of the plurality of regions; and
generating, for each of the plurality of regions, a respective modified image based on the corresponding image and the respective afterglow model.

5. The method according to claim 1, wherein the first image data comprises a set of electron backscatter diffraction pattern, EBSP, images, each comprising a respective subset of the plurality of pixels having values representing a respective subset of the monitored electrons emitted from the specimen at a respective location of the plurality of locations,
wherein the method comprises generating, for each of the set of EBSP images, a respective modified image comprising a plurality of pixels, each pixel having a value calculated based on the value of a corresponding pixel of the EBSP image and the afterglow model.

6. The method according to claim 1, wherein the generating of the modified image comprises, for each of the plurality of pixels thereof:
obtaining scintillator state data representative of energization, at the start of a monitoring period, of the scintillator member by electrons incident on the scintillator member prior to the monitoring period, wherein the monitoring period is the period of time during which the electrons emitted from the specimen at the location corresponding to the pixel are monitored so as to obtain the value of the corresponding pixel of the first image data; and
calculating the value of the pixel in accordance with the scintillator state data.

7. The method according to claim 6, wherein the obtained scintillator state data is representative of electrons incident upon the scintillator member and emitted from the specimen at each of a set of one or more calibration locations as a result of the electron beam impinging upon the set of calibration locations prior to impinging on the location corresponding to that one of the plurality of pixels.

8. The method according to claim 7, wherein each of the calibration locations is different from each of the plurality of locations.

9. The method according to claim 7, wherein the first image data comprises pixel values obtained by way of the electron beam traversing the region of the specimen according to a raster pattern; and
wherein the set of calibration locations comprises one or more locations along a flyback path comprised by the raster pattern.

10. The method according to claim 7, wherein the scintillator state data is derived from data obtained from the EBSD detector while the electron beam is being caused to impinge upon a first calibration location for a calibration time period; and
wherein the calibration time period is immediately prior to a monitoring period for a pixel of the first image data.

11. The method according to claim 10, wherein the first calibration location is a first location, of the plurality of locations, on which the electron beam impinges during acquiring the first image data; and
wherein the calibration time period is greater than or equal to a luminescence decay time period of the scintillator member.

12. The method according to claim 11,
wherein the scintillator state data further comprises data derived from the EBSD detector while the electron beam is being caused to impinge upon one or more further calibration locations for one or more respective calibration time periods, wherein each calibration time period is immediately prior to a monitoring period for a respective pixel of the first image data;
wherein each further calibration location is a respective first location, of the plurality of locations, on which the electron beam impinges during acquiring a respective portion of the first image data; and
wherein, for each further calibration location, the respective calibration time period is greater than or equal to a luminescence decay time period of the scintillator member.

13. The method according claim 6, wherein the scintillator state data is obtained in accordance with the first image data and beam path data indicative of a path on the specimen traversed by the beam.

14. The method according to claim 13, wherein the obtaining of the scintillator state data comprises calculating an estimated energization, at the start of a monitoring period, of the scintillator member by electrons emitted from the specimen as a result of the electron beam impinging on the beam path and incident on the scintillator member prior to the monitoring period, based on, for each of one or more pixels of the first image data, the pixel value and a positional relationship between the corresponding location and the beam path.

15. The method according to claim 1, the method further comprising:
causing the electron beam of the scanning electron microscope to impinge upon the plurality of locations within the region of the specimen; and
monitoring, using the EBSD detector, the resulting electrons emitted from the specimen at the plurality of locations and incident upon the scintillator member of the EBSD detector so as to obtain the first image data.

16. The method according to claim 15, wherein the method further comprises causing the beam not to impinge upon the sample during a blanking period immediately prior to the monitoring period, wherein a duration of the blanking period is greater than or equal to a luminescence decay time period of the scintillator member, or wherein the electron beam is caused to impinge upon the plurality of locations according to a continuous scan pattern.

17. A system for obtaining a modified image of a specimen in a scanning electron microscope, the system comprising:
an electron backscatter diffraction, EBSD, detector and a processor,
the system being configured to:
acquire first image data, the first image data comprising a plurality of pixels having values representing monitored electrons emitted from the specimen, at a plurality of locations within a region thereof as a result of an electron beam of the scanning electron microscope impinging upon the plurality of locations, and incident upon a scintillator member of the EBSD detector; and
generate a modified image comprising a plurality of pixels each having a value calculated based on the value of a corresponding pixel of the first image data and an afterglow model representative of a luminescence persistence characteristic of the scintillator member.

18. The system according to claim 17, wherein the system is configured such that:
one or more virtual detector regions of the scintillator member may be defined,
whereby the first image data comprises, for each of the one or more virtual detector regions, a first image comprising a respective plurality of pixels, each pixel which corresponds to, and has a value representing the monitored electrons incident on the virtual detector region and emitted from, a location of the plurality of locations.

19. A scanning electron microscope comprising the system according to claim 17.

20. A computer program product comprising instructions which, when executed by a computer, cause the computer to carry out the method of claim 1.
